(19) United States
(12) Patent Application Publication
(10) Pub. No.: US 2018/0351296 A1
(43) Pub. Date: Dec. 6, 2018

(54) Plug Connection for use in a Magnetic Resonance Device

(71) Applicant: Siemens Healthcare GmbH, Erlangen (DE)

(72) Inventor: Daniel Driemel, Oederan (DE)

(21) Appl. No.: 15/993,367

(22) Filed: May 30, 2018

(30) Foreign Application Priority Data
May 31, 2017 (EP) 17173640.8

(51) Int. Cl. H01R 13/629; H01R 13/44; G01R 33/34

(52) U.S. Cl. CPC H01R 13/62988; G01R 33/34007; H01R 13/44

(57) ABSTRACT

A plug connection, a first connecting part and a second connecting part of the plug connection, a patient couch, and a local coil are provided. The plug connection includes a first connecting part with at least one first contact module and a second connecting part with at least one second contact module. The first connecting part and the second connecting part are detachably connectable to one another. The first connecting part includes a housing. The first connecting part includes a displacement unit configured, during a connection of the first connecting part to the second connecting part, to move the at least one first contact module relative to the housing of the first connecting part in a direction of the at least one second contact module, in order to establish contact between the at least one first contact module and the at least one second contact module.

This application claims the benefit of EP17173640.8, filed on May 31, 2017, which is hereby incorporated by reference in its entirety.

### BACKGROUND

The present embodiments relate to a plug connection for use in a magnetic resonance device, a first connecting part and a second connecting part of the plug connection, a patient couch, and a local coil.

In medical technology, imaging by magnetic resonance (MR) (e.g., magnetic resonance imaging (MRI)) is characterized by high and variable soft tissue contrasts. Here, with the aid of a magnetic resonance device, excitation pulses are irradiated into a patient. The excitation pulses trigger magnetic resonance signals in the patient. The magnetic resonance signals are received by electrically-conductive loops (e.g., coils and/or antennas). In this process, a voltage is induced in the coil by a magnetic resonance signal. The induced voltage may be forwarded, amplified by a low-noise pre-amplifier, to receiving electronics of the magnetic resonance device.

The receive coils may be arranged as close as possible to the patient. The receive coils are therefore also referred to as local coils. Usually, the local coils are not permanently connected to the magnetic resonance device, but are connected to the magnetic resonance device via a plug connection.

Conventional plug connections, for example, include a first connecting part on the device side (e.g., a socket on a patient couch of the magnetic resonance device) and a second connecting part on the coil side (e.g., a plug on a cable of the local coil or also a direct connection), such as is disclosed, for example, in the publications US 2013 0184563 A1, US 2010 0156420 A1, and US 2013 0023756 A1.

The coil-side plug often includes contact elements (e.g., contact pins pointing outwards) that are freely able to be touched. Thus, the danger exists of mechanical damage, such as through bending of the contact pins.

The socket corresponding to the plug may include contact elements (e.g., contact openings pointing inwards) that are arranged in an insulating body. The contact elements may generally be embodied so as not to be able to be touched by an operator or a patient. Therefore, conventional sockets often include a mechanical cover (e.g., with a spring-loaded sliding or hinged mechanism). The cover may protect against touching the contact elements directly and/or against the ingress of liquids. However, these covers may also be opened without a plug (e.g., unwittingly by the patient), which may lead to damage and/or injuries.

For example, when the cover is open, liquids may still enter into the insulating body and lead, for example, to a corrosion of a printed circuit board that may be connected thereto. After cleaning, residues of liquid from cleaning agents may remain in the socket, which may cause material fatigue, since the cleaning agents may collect in indentations of the socket and have an effect over a long period.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a magnetic resonance (MR)-compatible plug connection that is convenient and safe to handle is provided.

A plug connection for use in a magnetic resonance device that includes a first connecting part with at least one first contact module and a second connecting part with at least one second contact module is provided. The first connecting part and the second connecting part are embodied to be connected detachably to one another. The first connecting part includes a housing. The first connecting part includes a displacement unit (e.g., mechanical displacement unit) that is embodied, on connection of the first connecting part to the second connecting part, to move the at least one first contact module relative to the housing of the first connecting part in a direction of the at least one second contact module, in order to establish a contact between the at least one first contact module and the at least one second contact module. In this case, the contact may be an immediate and/or direct and/or touching contact.

A mechanism of this type may advantageously enable a stable plug state to be established, since through the relative movement of the first contact module in relation to the housing of the first connecting part, the first contact module and the second contact module may be brought together safely. Any protective covers may advantageously be dispensed with.

The first connecting part may be arranged on a patient couch, for example. The housing of the first connecting part may, for example, be connected in one piece with the patient couch (e.g., with a housing of the patient couch). For example, the first connecting part may be integrated into a housing of the patient couch, so that the housing of the patient couch is simultaneously the housing of the first connecting part. An integration of the first connecting part into the patient couch, for example, enables any individual parts and interfaces between such individual parts to be avoided. The plug connection may thus advantageously be cleaned especially well.

In one embodiment, during a connection of the first connecting part to the second connecting part, the at least one first contact module may be moved in a horizontal direction relative to the housing of the first connecting part. This possibly enables an undesired ingress of liquids to be avoided.

The second connecting part may, for example, include a manual plug of a local coil (e.g., the manual plug is connected to any antennas of the local coil via a flexible cable), so that the local coil may be positioned flexibly on a patient couch.

The second connecting part may also include, for example, a cableless direct plug of a local coil (e.g., of a head coil). In this case, for example, a housing of the second connecting part may be connected in one piece (e.g., rigidly to a local coil). For example, the second connecting part may be integrated into a housing of the local coil, so that the housing of the local coil is simultaneously the housing of the second connecting part. Direct plug connections advantageously make possible an especially simple and convenient workflow.

A detachable connection may be a connection that may be released and/or used for a plurality of connection and/or disconnection processes, without destroying the connection (e.g., used repeatedly without destroying the connection).

A mechanical displacement unit may be a unit that is embodied to move the at least one first contact module with the aid of mechanical forces. The use of magnetic forces, because of possible interaction with any magnetic fields that are generated by a magnetic resonance device, is thus not suitable.

The first connecting part and the second connecting part may be brought into contact with one another to establish a connection and/or taken apart to disconnect a connection. The plug connector may thus be embodied to disconnect and/or to connect lines (e.g., electrical lines), via which, for example, magnetic resonance signals may be transmitted. Since the plug connection is intended for use in a magnetic resonance device, the plug connection may include exclusively MR-compatible (e.g., non-magnetic) materials.

The plug connection may be an electrical plug connection (e.g., in a connected state, at least one electrical contact is established between the first connecting part and the second connecting part). Electrical signals and/or electrical energy may be transmitted via the at least one contact.

In one embodiment, the first contact module and the second contact module each have at least one electrically-conductive contact element (e.g., an electrical contact). In one embodiment, in a connected state, the at least one electrically-conductive contact element of the first contact module is connected to the at least one electrically-conductive contact element of the second contact module (e.g., directly).

A relative movement of the at least one first contact module in relation to the housing of the first connecting part may be a movement in which the position and/or location of the at least one first contact module changes in relation to the housing of the first connecting part. The at least one first contact module is thus embodied to enable movement relative to the housing of the first connecting part.

In one embodiment, the plug connection is embodied such that, during a connection of the first connecting part to the second connecting part, the at least one first contact module is moved relative to the housing of the first connecting part in the direction of the at least one second contact module. This connection direction may thus be oriented during a connection such that, during the movement, a distance between the at least one first contact module and the at least one second contact module reduces.

In one embodiment, the displacement unit is embodied, during a disconnection of the first connecting part from the second connecting part, to move the at least one first contact module relative to the housing of the first connecting part in a disconnection direction, which is oriented opposite to the connection direction, in order to break the contact between the at least one first contact module and the at least one second contact module.

An embodiment of the plug connection makes provision for the displacement unit to be embodied, during a connection of the first connecting part to the second connecting part, to transmit a force (e.g., a mechanical force) from the second connecting part to the at least one first contact module.

This transmitted force may be used, for example, to support the movement of the at least one first contact module relative to the housing of the first connecting part (e.g., to bring about the movement).

An embodiment of the plug connection makes provision for the displacement unit of the first connecting part to include a first force transmission unit and for the second connecting part to include a second force transmission unit. In this case, during a connection of the first connecting part to the second connecting part by the second force transmission unit, a first force (e.g., a mechanical force) is introduced into the first force transmission unit, so that a second force (e.g., a mechanical force) is introduced into the first contact module.

The first force transmission unit and the second force transmission unit, for example, enable an external force from outside the first connecting part to be introduced into the displacement unit in order to support the movement of the at least one first contact module relative to the housing of the first connecting part (e.g., to bring about the movement). For example, an external movement of the second connecting part enables the first force to be introduced into the first force transmission unit, so that the movement of the at least one first contact module relative to the housing of the first connecting part may be influenced from outside (e.g., from outside the housing of the first connecting part).

The first force transmission unit and the second force transmission unit are adapted to one another so that the relative movement of the at least one first contact module may only be initiated by the second force transmission unit. This advantageously enables an undesired actuation of the at least one first contact module to be prevented.

In one embodiment of the plug connection, the housing of the first connecting part may have at least one recess. In this case, the second force transmission unit has at least one projecting element that is able to be arranged in (e.g., inserted into) the at least one recess of the housing.

For example, the at least one projecting element and the at least one recess are embodied corresponding to one another. For example, the shape and/or size of the at least one projecting element and of the at least one recess are embodied corresponding to one another, so that, for example, the at least one projecting element fits into the at least one recess. Advantageously, the recess is dimensioned so that there may not be any undesired actuation of the first force transmission unit (e.g., by a finger of a patient).

In one embodiment, during a connection of the first connecting part to the second connecting part, the at least one projecting element may be inserted into the at least one recess. This insertion movement, for example, enables the first force to be introduced via the at least projecting element into the first force transmission unit (e.g., by the at least one projecting element pushing the first force transmission unit away from the at least one projecting element).

This, for example, enables a controlled (e.g., guided) introduction of force to be made possible.

In one embodiment, the displacement unit includes at least one diversion lever (e.g., a rotatably supported lever) that diverts the first force to the second force. Using such a lever, a force diversion may be realized in a simple and efficient manner.

In one embodiment, the at least one lever is arranged within the housing of the first connecting part. In one embodiment, the at least one lever is supported at a pivot point that divides the at least one lever into a first side and a second side. In one embodiment, the first side of the at least one lever is arranged on the first force transmission unit. In one embodiment, the second side of the at least one lever is arranged on the at least one first contact module.

The embodiment of the at least one lever and/or of the pivot point enable different transmission ratios between a path of the first force transmission unit and a path of the first contact module to be realized.

In one embodiment, the displacement unit has a lever in each case for each first contact module. This enables the relative movement to be carried out in an especially reliable manner.

In one embodiment, the second force includes a component that is aligned in opposition to the first force. For example, the first connecting part includes a guide for the at least one first contact module, which under the effect of the second force, brings about a movement of the at least one first contact module at the at least one first contact module, which is aligned opposite to the first force. In one embodiment, any components of the second force that are not aligned in opposition to the first force may be accommodated by this guide.

In one embodiment, the displacement unit includes at least one spring unit that acts in opposition to the first force. In a disconnected state of the plug connection, this enables the first force transmission unit to be held in a pre-tensioned initial state. The at least one spring unit may include at least one compression spring (e.g., a cylindrical spring).

In one embodiment, the second connecting part includes at least one latching element that holds the second connecting part in a connected state. For example, the latching element is able to counteract any spring force of the at least one spring unit.

In one embodiment of the plug connection, the at least one first contact module, in a disconnected state, may be flush and/or set back in relation to an adjoining outer surface of the housing of the first connecting part. This enables the first contact module to be protected from damage and/or contamination.

During a connection of the first connecting part to the second connecting part, the at least one first contact module may be moved out beyond the adjoining outer surface of the housing of the first connecting part, so that, in a connected state, the at least one first contact module projects beyond this surface.

In one embodiment of the plug connection, the at least one first contact module may include electrically-conductive contact elements that, in an unconnected state, are located within the housing of the first connecting part. Inadvertent touching of the electrically-conductive contact elements may thus be avoided.

Such an arrangement, for example, enables the contact elements to be protected from damage and/or contamination, since the contact elements do not provide any vulnerable external surfaces.

In one embodiment, the at least one first contact module includes electrically-conductive contact elements that are embodied as planar elements in at least one plane (e.g., two parallel planes). The at least one plane is essentially embodied in parallel to the direction in which the at least one first contact module moves during a connection of the first connecting part to the second connecting part.

In one embodiment, the contact elements, which in an unconnected state, are visible from outside, are not arranged on an end face side of the at least one first contact module, but, for example, are arranged in a plane aligned perpendicular thereto.

This represents an advantageous arrangement for protecting the contact elements from damage and/or contamination in an unconnected state.

In one embodiment, the second connecting part includes a housing with at least one recess, where the at least one first contact module, during a connection of the first connecting part to the second connecting part, is introduced into the at least one recess of the housing of the second connecting part.

The at least one first contact module moves into the at least one recess of the housing of the second connecting part during a connection of the first connecting part to the second connecting part in order to establish contact between the at least one first contact module and the at least one second contact module.

The at least one second contact module may be arranged within the at least one recess of the housing of the second connecting part. This internal arrangement enables the second contact module to be better protected against dirt and/or damage.

In one embodiment, the at least one second contact module includes at least one electrically-conductive contact element that is spring-loaded. Spring loading enables these contact elements to make especially reliable contact with the contact elements of the first contact module. This enables manufacturing tolerances to be allowed for and/or sliding contacting processes to be implemented.

In one embodiment of the plug connection, the second connecting part, during a connection of the first connecting part to the second connecting part, may be guided as a form fit. Such forced guidance may be provided, for example, by the housing of the connecting part having a shape (e.g., a V shape and/or a groove and/or a tongue) that makes a form fit with a mating piece.

In one embodiment, such a forced guidance enables a convenient and safe (e.g., tilt-free) connection or disconnection of the plug connection to be achieved.

A first connecting part that is embodied to make a plug connection with a second connecting part is provided. A second connecting part that is embodied to make a plug connection with a first connecting part is provided.

A patient couch with at least one first connecting part is provided. A local coil with at least one second connecting part is also provided.

In one embodiment, the at least one first connecting part is arranged on the patient couch such that, during a connection of the first connecting part to a second connecting part, the at least one first contact module is moved relative to the housing of the first connecting part, in a direction parallel to a couch surface of the patient couch (e.g., usually a horizontal direction.) This possibly enables an undesired ingress of liquids to be avoided.

Further details about the first connecting part and the second connecting part and also about the patient couch and the local coil are provided above.

### BRIEF DESCRIPTION OF THE DRAWINGS

Parts that correspond to one another are labeled with the same reference characters in all figures.

FIG. 1 shows one embodiment of a magnetic resonance device with a patient couch, a local coil, and a plug connection between the local coil and the patient couch, in a schematic diagram;

FIG. 2 shows an exemplary plug connection in an unconnected state, in a schematic diagram;

FIG. 3 shows an exemplary plug connection in a connected state, in a schematic diagram;

FIG. 4 shows one embodiment of a second connecting part and a patient couch with three first connecting parts, in a detailed diagram;

FIG. 5 shows one embodiment of a second connecting part, in a detailed diagram; and

FIG. 6 shows an internal view of one embodiment of a first connecting part.

### DETAILED DESCRIPTION

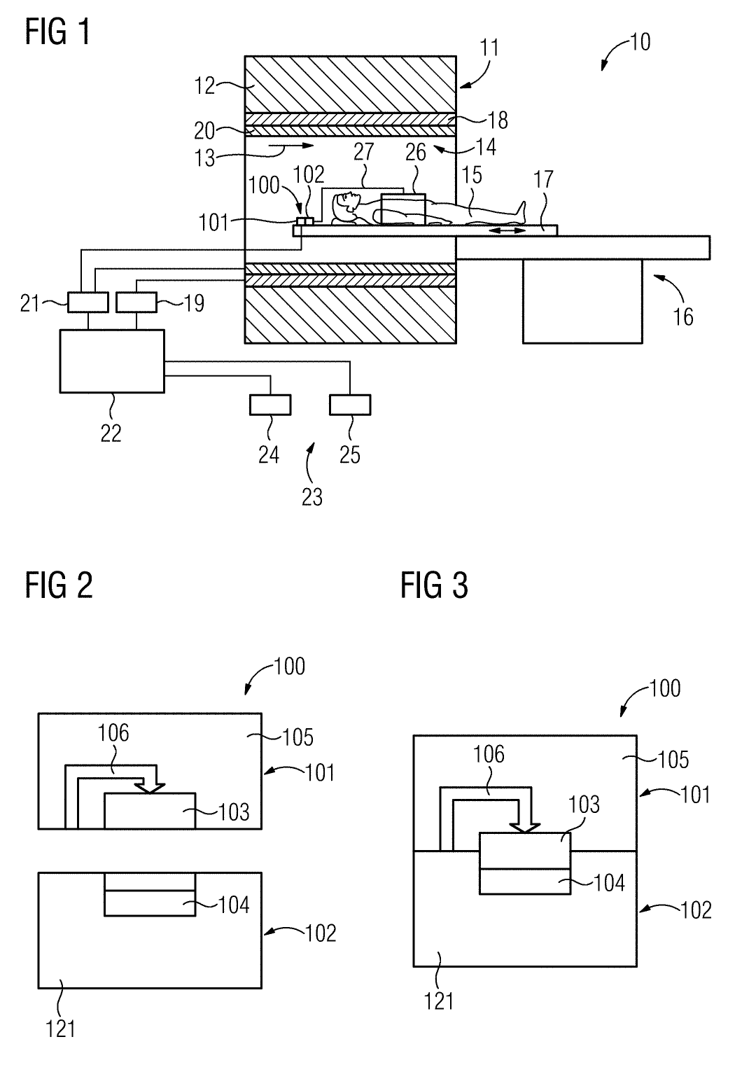

FIG. 1 shows a schematic of one embodiment of a magnetic resonance device 10. The magnetic resonance device 10 includes a magnet unit 11 that has a main magnet 12 for creating a strong and, for example, temporally constant main magnetic field 13. The magnetic resonance device 10 has a patient receiving area 14 for receiving a patient 15. The patient receiving area 14, in the present exemplary embodiment, is embodied in a cylindrical shape and is surrounded in a circumferential direction by the magnet unit 11 in a cylindrical shape. An embodiment of the patient receiving area 14 deviating therefrom may, however, be provided. The patient 15 may be pushed into the patient receiving area 14 by a patient support facility 16 of the magnetic resonance device 10. The patient support facility 16 has a patient couch 17 embodied so that the patient couch 17 may be moved within the patient receiving area 14. The patient is supported by, for example, lying on a surface of patient couch 17.

The magnet unit 11 also has a gradient coil unit 18 for creation of magnetic field gradients that are used for spatial encoding during imaging. The gradient coil unit 18 is controlled by a gradient control unit 19 of the magnetic resonance device 10. The magnet unit 11 further includes a radio frequency antenna unit 20 that is configured in the present exemplary embodiment as a body coil integrated permanently into the magnetic resonance device 10. The radio frequency antenna unit 20 is configured to excite atomic nuclei that occur in the main magnetic field 13 created by the main magnets 12. The radio frequency antenna unit 20 is controlled by a radio frequency antenna control unit 21 of the magnetic resonance device 10 and radiates radio-frequency magnetic resonance sequences into an examination space that is essentially formed by a patient receiving area 14 of the magnetic resonance device 10.

The patient couch 17 includes a first connecting part 101.

The magnetic resonance device 10 further includes a local coil 26 with a cable 27 and a second connecting part 102 configured as, for example, a manual plug. The first connecting part 101 and the second connecting part 102 form a plug connection 100 with each other. The local coil 26 is configured to receive magnetic resonance signals that may be transmitted via the plug connection 100 for further processing.

To control the main magnets 12, the gradient control unit 19, and to control the radio frequency antenna control unit 21, the magnetic resonance device 10 has a system control unit 22. The system control unit 22 controls the magnetic resonance device 10 centrally, such as, for example, carrying out a prespecified magnetic resonance imaging sequence. The system control unit 22 includes an evaluation unit not shown in FIG. 1 for evaluating the magnetic resonance signals that are acquired during the magnetic resonance examination. The magnetic resonance device 10 also includes a user interface 23 that is connected to the system control unit 22. Control information such as imaging parameters, for example, and also reconstructed magnetic resonance images may be displayed on a display unit 24 (e.g., on at least one monitor) of the user interface 23 for an operator. The user interface 23 also has an input unit 25, by which information and/or parameters may be entered by the operating personnel during a measuring process.

FIG. 2 and FIG. 3 show examples in each case of a plug connection 100 for use in a magnetic resonance device 10 in various states (e.g., FIG. 2 in a disconnected state and FIG. 3 in a connected state). The plug connection 100 includes a connecting part 101 with a first contact module 103 and a second connecting part 102 with a second contact module 104. The first connecting part 101 and the second connecting part 102 are detachably connectable to each other. The second connecting part 102 includes a housing 121. The first connecting part further includes a housing 105 and a displacement unit 106. The displacement unit 106 is embodied, during a connection of the first connecting part 101 to the second connecting part 102, to move the first contact module 103 relative to the housing 105 of the first connecting part 101 in the direction of the second contact module 104 in order to establish contact between the first contact module 103 and the second contact module 104. The further figures show exemplary embodiments of such a plug connection 100.

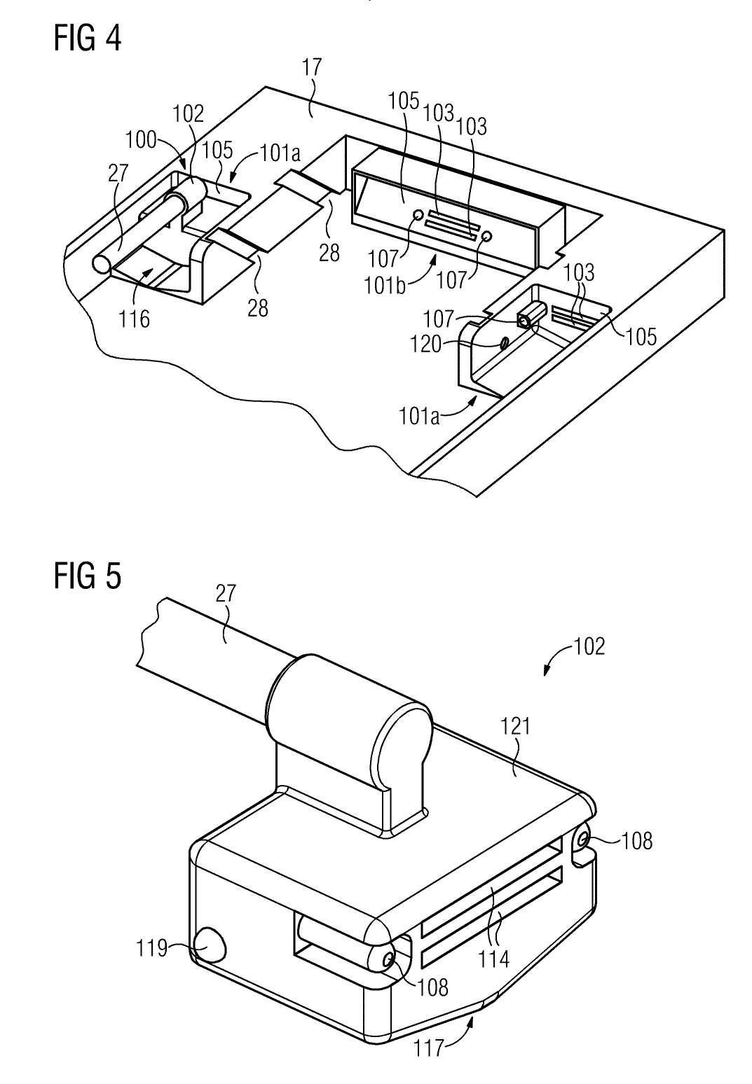

FIG. 4 shows a detailed diagram of a section of the patient couch 17. In this example, the patient couch 17 includes three first connecting parts 100a, 100b. The connecting parts 100a, 100b form plug-in locations for making contact with one or more local coils 26. The two first connecting parts 101a are embodied to make a plug connection 100 with a second connecting part 102 in the form of a manual plug. Manual plugs may be used for making contact with local coils able to be used in different positions on the patient couch 17 such as, for example, a body coil and/or a flex coil. Such local coils may be connected via a cable 27 to the second connecting part 102.

A further first connecting part 100b is embodied to make a plug connection to a second connecting part in the form of a direct plug. Direct plugs may be used for making contact with fixed-location local coils such as, for example, a head coil that may be plugged in via, for example, guide rails 28.

The first connecting parts 100a, 100b each include two first contact modules 103. In this view, the two first contact modules of the plug connection 100 shown on the left are hidden by the second connecting part 102.

For the housing 105 of the first connecting part, connecting parts 100a, 100b each include two recesses, into which first force transmission units 107 (e.g., first force transmitters; in the form of push rods) are arranged as part of a displacement unit. The second connecting parts 102 include second force transmission units 108 (e.g., second force transmitters) corresponding thereto, with projecting elements, as are shown by way of example in FIG. 5 in the form of guide pins. The projecting elements are able to be arranged in the recesses, so that on connection of the displacement units, second force transmission units 108 move the first force transmission units 107.

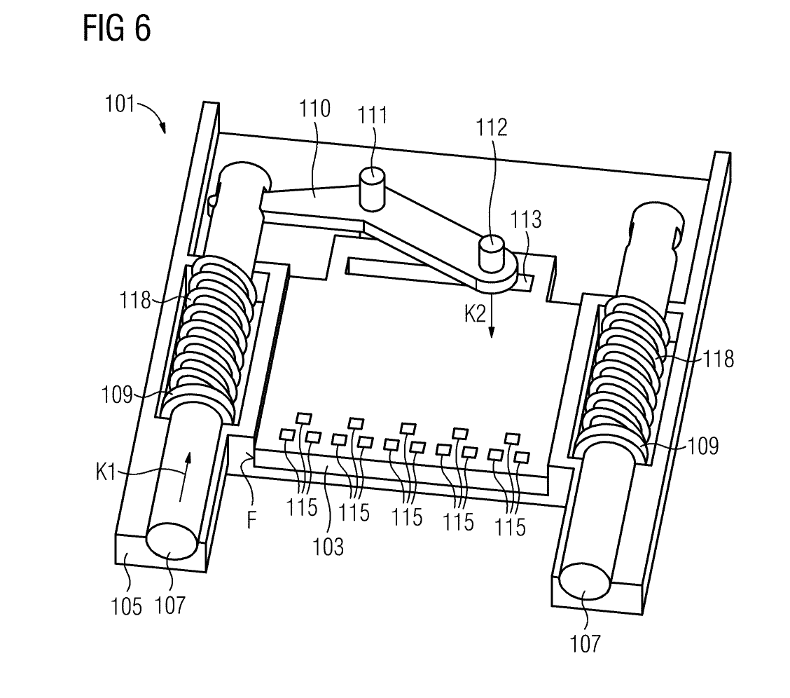

For movement of the contact module 103, the second force transmission units 108, of the second connecting part 102 (e.g., of the manual plug) push the first force transmission units 107 into the patient couch 17. During this process, a force (e.g., a mechanical force) is transmitted from the second connecting part 102 to the first contact module. For example, during a connection of the first connecting part 101 to the second connecting part 102 by the first force transmission unit, a first force K1 (e.g., a mechanical force) is introduced into the second force transmission unit, so that a second force K2 (e.g., a mechanical force) is introduced into the first contact module 103, as will be explained below with reference to FIG. 6.

The displacement unit includes a spring unit 118 (e.g., a compression spring) that counteracts the first force K1. The first force transmission unit 107 actuates the spring unit 118, which realizes a backwards movement of the contact module 103 after the contacting is released, but only touches the housing 105 of the first connecting part 101 as far as a stop 109 of the first force transmission unit 107. This, for example, enables too great an inwards movement of the first contact module to be prevented.

The movement of the first force transmission unit 107 is diverted via a lever 110 that reaches down into the first force transmission unit 107 and is supported pivotably by a shaft (e.g., the pivotably supported lever diverts the first force K1 to the second force K2). In this case, the second force K2 is aligned in opposition to the first force K1.

Via a stud 112 that, with an elongated slot 113 in the first contact module 103, forms a shift link, the first contact module 103 is pushed from a parking position in the patient couch 17 into a recess 114, such as is shown, for example, in FIG. 5 as a slot, of a housing 121 of the second connecting part 102 (e.g., the first contact module 103) and is introduced during a connection of the first connecting part 101 to the second connecting part 102 into the recess 114 of the housing 121 of the second connecting part 102. The first contact module 103 is guided in the housing 105 without sticking by a linear guide.

The first contact module 103, in an unconnected state, as shown in FIG. 6, is flush or set back (e.g., slightly set back) in relation to an adjoining outer surface F of the housing 105 of the first connecting part 101. The first contact module includes electrically-conductive contact elements 115 that are located in an unconnected state within the housing 105 of the first connecting part 101.

The electrically-conductive contact elements 115 are embodied flat in a plane E, where the plane E is essentially oriented in parallel to the direction in which the first contact module 103 moves during a connection of the first connecting part 101 to the second connecting part 102.

The second contact module 104 in the housing 121 likewise includes electrically-conductive contact elements that may be arranged in the recess 114. The planar contact elements 115 are contacted electrically during a connection of the first connecting part 101 to the second connecting part 102 via the electrically-conductive contact elements of the second contact module 104. The electrically-conductive contact elements of the second contact module 104 may, for example, be embodied as spring-loaded (e.g., as bendable contact springs). The electrically-conductive contact elements 115 may be arranged on one side and/or on several sides (e.g., on two parallel planes) and/or on all sides of the first contact module 103.

The form of embodiment of the plug connection described in FIG. 4 includes two first contact modules 103 per plug-in location. However, just one first contact module 103 or more than two first contact modules 103 may also be provided. Likewise, the individual plug-in locations may be equipped differently. The shape of the contact module 103 is a flat design in the exemplary embodiment, but the contact module 103 may also have any other sensible shape. For example, the first contact module 103 may be embodied as a printed circuit board, on which the electrically-conductive contact elements 115 and optional conductor tracks for signal forwarding are present. This enables an especially low-cost first contact module 103 to be produced. For transfer of signals from first contact module 103 to the patient couch 17, electrical lines may be soldered or plugged in directly at the first contact module 103, for example.

As shown by way of example in FIG. 4 and FIG. 5, the second connecting part 102 has a V-shaped design 117 on a base side. The patient couch 17 has a matching mating shape 116 at the plug-in locations. In this way, a form fit that provides a better guidance of the first connecting part 102 is achieved. The form fit may also be configured with a different geometry (e.g., round, as a tongue and groove, etc.). At the moment that the second force transmission unit 108 penetrates into the recess of the housing 105 of the first connecting part 101, a forced guidance is created, so that the second connecting part may no longer tilt and the first contact module 103 penetrates into the recess 114 of the housing of the second connecting part 102.

Since contact is made against the force of the spring unit 118, the second connecting unit 102 is advantageously prevented from being pushed backwards again. This is secured in the second connecting part 102 (e.g., by sprung-supported latching elements 119 that penetrate into form-fit recesses 120 in the patient couch 17). As an alternative, corresponding recesses of the second connecting part 102, into which latching elements that are arranged on the patient couch may penetrate, may be provided. This enables the second connecting part 102 to be held in a connected state. The holding force is advantageously dimensioned so that the holding force is greater than an ejection force of the spring unit 118. In the event of a direct connection, this requirement may be fulfilled by the weight force of a head coil, for example. The plug-in force and the during pulling of the second connecting part may be applied by the operating personnel for a manual plug.

The method described and the acquisition pattern creation unit and magnetic resonance facility shown here merely involve exemplary embodiments that may be modified by the person skilled in the art in a very wide variety of ways, without departing from the field of the invention. The use of the indefinite article “a” or “an” does not exclude the features concerned also being present more than once. Likewise, the term “unit” does not exclude the components concerned consisting of a number of interacting sub-components that may also be distributed physically if necessary.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A plug connection for use in a magnetic resonance device, the plug connection comprising:
a first connecting part with at least one first contact module and a second connecting part with at least one second contact module,
wherein the first connecting part and the second connecting part are detachably connectable to one another,
wherein the first connecting part comprises a housing,
wherein the first connecting part comprises a displacement unit, the displacement unit being configured, during a connection of the first connecting part to the second connecting part, to move the at least one first contact module relative to the housing of the first connecting part in a direction of the at least one second contact module, such that contact between the at least one first contact module and the at least one second contact module is established.

2. The plug connection of claim 1, wherein the displacement unit is a mechanical displacement unit.

3. The plug connection of claim 1, wherein the displacement unit is configured, during a connection of the first connecting part to the second connecting part, to transmit a force from the second connecting part to the at least one first contact module.

4. The plug connection of claim 1, wherein the displacement unit of the first connecting part comprises a first force transmitter, and the second connecting part comprises a second force transmitter, and
wherein during a connection of the first connecting part to the second connecting part, the second force transmitter is configured to introduce a first force into the first force transmitter, so that a second force is introduced into the at least one first contact module.

5. The plug connection of claim 4, wherein the housing of the first connecting part comprises at least one recess, and
wherein the second force transmission unit comprises at least one projecting element that is arrangeable in the at least one recess of the housing.

6. The plug connection of claim 4, wherein the displacement unit comprises at least one pivotably supported lever operable to redirect the first force to the second force.

7. The plug connection of claim 4, wherein the second force comprises a component that is aligned in opposition to the first force.

8. The plug connection of claim 4, wherein the displacement unit comprises at least one spring unit operable to counteract the first force.

9. The plug connection of claim 1, wherein the second connecting part comprises at least one latching element that holds the second connecting part in a connected state.

10. The plug connection of claim 1, wherein the at least one first contact module, in an unconnected state, is flush, is set back in relation to an adjoining outer surface of the housing of the first connecting part, or is flush and set back in relation to the adjoining outer surface of the housing of the first connecting part.

11. The plug connection of claim 1, wherein the at least one first contact module comprises electrically-conductive contact elements that, in an unconnected state, are located within the housing of the first connecting part.

12. The plug connection of claim 1, wherein the at least one first contact module comprises electrically-conductive contact elements that, in at least one plane, are flat,
wherein the at least one plane is essentially oriented in parallel to a direction in which the at least one first contact module moves during a connection of the first connecting part to the second connecting part.

13. The plug connection of claim 1, wherein the second connecting part comprises a housing with at least one recess, and
wherein the at least one first contact module, during a connection of the first connecting part to the second connecting part, is insertable into the at least one recess of the housing of the second connecting part.

14. The plug connection of claim 1, wherein the at least one second contact module comprises electrically-conductive contact elements that are spring-loaded.

15. The plug connection of claim 1, wherein the second connecting part, during a connection of the first connecting part to the second connecting part, is guided to make a form fit.

16. A first connecting part configured to enter into a plug connection with a second connecting part, the first connecting part and the second connecting part being detachably connectable to one another, the first connecting part comprising:
at least one first contact module, wherein the second connecting part comprises at least one second contact module;
a housing; and
a displacement unit configured, during a connection of the first connecting part to the second connecting part, to move the at least one first contact module relative to the housing in a direction of the at least one second contact module, such that contact between the at least one first contact module and the at least one second contact module is established.

17. A connecting part configured to enter into a plug connection with another connecting part, the other connecting part comprising one or more contact modules, a housing, and a displacement unit, the connecting part and the other connecting part being detachably connectable to one another, the connecting part comprising:
at least one contact module, wherein during a connection of the other connecting part to the connecting part, the displacement unit of other connecting part is configured to move the one or more contact modules of the other connecting part relative to the housing of the other connecting part in a direction of the at least one contact module, such that contact between the one or more contact modules of the other connecting part and the at least one contact module is established.

18. A patient couch comprising:
a first connecting part configured to enter into a plug connection with a second connecting part, the first connecting part and the second connecting part being detachably connectable to one another, the first connecting part comprising:
at least one first contact module, wherein the second connecting part comprises at least one second contact module;
a housing; and
a displacement unit configured, during a connection of the first connecting part to the second connecting part, to move the at least one first contact module relative to the housing in a direction of the at least one second contact module, such that contact between the at least one first contact module and the at least one second contact module is established.

19. A local coil comprising:
a connecting part configured to enter into a plug connection with another connecting part, the other connecting part comprising one or more contact modules, a housing, and a displacement unit, the connecting part and the other connecting part being detachably connectable to one another, the connecting part comprising:
at least one contact module, wherein during a connection of the other connecting part to the connecting part, the displacement unit of other connecting part is configured to move the one or more contact modules of the other connecting part relative to the housing of the other connecting part in a direction of the at least one contact module, such that contact between the one or more contact modules of the other connecting part and the at least one contact module is established.
